(19) United States
(12) Patent Application Publication
(10) Pub. No.: US 2008/0230878 A1
(43) Pub. Date: Sep. 25, 2008

(54) Leadframe based flip chip semiconductor package and lead frame thereof

(75) Inventors: Wei-Lung Lu, Taichung (TW); Chih-Nan Lin, Taichung (TW); Shih-Kuang Chiu, Taichung (TW); Chin-Te Chen, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/077,489

(22) Filed: Mar. 19, 2008

(30) Foreign Application Priority Data
Mar. 21, 2007 (TW) 096109662

(51) Int. Cl. H01L 23/495

(52) U.S. Cl. 257/667; 257/673; 257/E23.039; 257/E23.033

(57) ABSTRACT

A flip chip semiconductor package is disclosed according to the present invention, the flip chip semiconductor package comprises a chip that is mounted on and electrically connects to a leadframe via a plurality of solder bumps by means of flip chip, and an encapsulate that encapsulates the chip, the plurality of solder bumps, and the leadframe, wherein, the leadframe further comprises a plurality of leads and a ground plane that is located between the plurality of leads, and also a slit is formed on the ground plane, and then a molding compound that makes up the encapsulant should be capable of filling within the slit, thus to enhance the adhesion between the ground plane and the encapsulant, and then avoid delamination between the ground plane and the encapsulant in subsequent thermal cycle processes, thereby increasing the reliability of fabricated products.

### FIELD OF THE INVENTION

The present invention relates to flip-chip semiconductor package techniques, and more particularly, to a lead-frame based flip chip semiconductor package.

### BACKGROUND OF THE INVENTION

Referring to FIG. 1, a prior-art Flip Chip Quad Flat Non-Leaded (FCQFN) semiconductor package is fabricated by mounting a chip 11 on a lead frame 12 via a plurality of solder bumps 10 by flip-chip technique; electrically connecting the chip 11 to the lead frame 12; encapsulating the chip 11, the lead frame 12, and the plurality of solder bumps 10 by an encapsulant 13, wherein, after the encapsulant 13 is formed, the side surface 120a and bottom surface 120b of each lead 120 of the lead frame 12 are exposed from the encapsulant 13 and the bottom surface 120b of each lead 120 is flushed with the bottom surface 13b of the encapsulant 13, such that none of the leads 120 is protruded from the encapsulant 13 in a completed semiconductor package 1, so as to reduce spaces occupied by the semiconductor package, when disposing the semiconductor package on a printed circuit board (not shown). Techniques similar to the aforementioned are disclosed in U.S. Pat. Nos. 6,507,120, 6,590,281, and 6,700,187.

Nevertheless, if the heat generated during chip operation is increased due to increasing demand of electricity in presence of a highly-integrated chip, each of the leads of the foregoing FCQFN semiconductor package can hardly fulfill its role as a grounding and heat dissipating element. Therefore, another semiconductor package is developed to overcome the foregoing drawbacks by connecting ground leads of a lead frame or forming a large ground plane on the lead frame, wherein the connected ground leads or ground plane is electrically connected to a chip via a plurality of dummy bumps or ground bumps that are pre-mounted on the chip. This thereby allows heat generated by the chip to be dissipated to the connected ground leads or ground plane via the dummy bumps or ground bumps. Moreover, because the connected ground leads or ground plane is configured to have larger areas for grounding and heat dissipation, it can enhance electrical performance and heat dissipation efficiency.

As shown in FIGS. 2A and 2B, U.S. Pat. No. 6,597,059 discloses a semiconductor package 2 similar to the aforementioned. The semiconductor package 2 comprises a lead frame 22 having a plurality of leads 220 and a ground plane 221 disposed between the leads 220; a chip 21 bonded to the leads 220 and the ground plane 221 via a plurality of solder bumps 20a and a plurality of ground bumps 20b respectively, such that the chip 21 is electrically connected to the lead frame 22; and an encapsulate 23 for encapsulating the chip 21, the lead frame 22, the solder bumps 20a, and the ground bumps 20b.

Although the semiconductor package 2 is configured with a larger ground plane 221 to provide better electricity and heat dissipation efficiency, the ground plane 221 as such can only adhere to the encapsulant 23 by a lateral surface 221a of the ground plane 221 and a portion of a top surface 221b of the ground plane 221, and therefore the adhesion between the ground plane 221 and the encapsulant 23 is quite poor and weak, and even unstable, thereby causing delamintaion between the ground plane 221 and the encapsulant 23 during the subsequent thermal cycling due to mismatch of the coefficient of thermal expansion (CTE), as shown by a letter ‘D’ in FIG. 2C. Moreover, occurrence of the delamination not only severely damages the structure of the semiconductor package 2, but also allows mist from ambient to enter the semiconductor package 2 and brings on popcorn effect, which causes further irreparable damages, thereby jeopardizing the reliability of the semiconductor package 2. Besides, as the ground plane 221 of the semiconductor package 2 is relatively larger, great and more thermal stresses are generated by such ground plane 221 during the thermal cycling, thereby increasing the likelihood of causing delamination between the ground plane 221 and the encapsulant 23.

Hence, a need still remains for providing a technique that can effectively solve the aforementioned drawbacks, and provide sufficient electricity and good performance of heat dissipation.

Solutions to these problems have been long sought but prior developments have not taught or suggested any solutions and, thus, solutions to these problems have long eluded those skilled in the art.

### SUMMARY OF THE INVENTION

In light of the shortcomings of the above prior arts, a primary objective of the present invention is to provide a leadframe-based flip chip semiconductor package and a lead frame applicable thereto, which can prevent delamination between a ground plane of the lead frame and an encapsulant of the semiconductor package.

Another objective of the present invention is to provide a leadframe-based flip chip semiconductor package and a lead frame applicable thereto, which can allow a ground plane of the lead frame to be firmly adhered to an encapsulant of the semiconductor package.

To achieve the aforementioned and other objectives, a leadframe-based flip chip semiconductor package and a lead frame applicable thereto is provided in the present invention. The flip chip semiconductor package comprises: a chip having a plurality of solder bumps and a plurality of ground bumps mounted thereon; a lead frame having a plurality of leads and a ground plane disposed between the leads, wherein the ground plane further comprises a slit; and an encapsulant for encapsulating the chip, the solder bumps, the ground bumps, and the leadframe, wherein the external lateral surfaces and bottom surfaces of the leads and that of the ground plane are exposed from the encapsulant, and furthermore, the bottom surface of the ground plane is flushed with the bottom surface of the encapsulant. In addition, the solder bumps are soldered in position correspondingly to the leads, and the ground bumps are soldered in position corresponding to portions of the ground plane.

Moreover, the present invention further provides a lead frame, which is applicable to a flip chip semiconductor package partially encapsulated by an encapsulant. The leadframe comprises a plurality of leads and a ground plane formed between the leads, wherein the ground plane further comprises a slit allowing at least a portion of the encapsulant to be filled thereto.

Additionally, the width of the slit is not restricted as long as it is wide enough to receive at least a portion of the encapsulant. The slit may be linear, non-linear, sinuous, triangular, curved, circled or any shape according to one's need. In other words, there is no restriction on the shape or width of the slit, however, a slit that is not linear may provide a larger adhering area between the encapsulant and the ground plane for receiving the encapsulant than that of the linear slit. Accordingly the slit that is not linear may provide greater adhesion between the ground plane and the encapsulant. Moreover, the slit may be formed anywhere in the ground plane, however it is preferably to form the slit in the middle of the ground plate, so as to drastically diminish the thermal stress of ground plane during the thermal cycling.

Furthermore, portions of the ground bumps are disposed across the slit, so as to electrically connect the two splitting portions of ground plane separated by the slit, thereby avoiding electricity and heat dissipation efficiency provided by the ground plane from being affected by the formation of slit.

Accordingly, due to formation of the slit, the ground plane is capable of receiving at least a portion of the encapsulant and being firmly adhered to the encapsulant, so as to prevent delamination between the ground plane and the encapsulant during the thermal cycling, thereby enhancing reliability of the semiconductor package in the present invention.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF DRAWINGS

The present invention can be more fully understood by reading the following detailed description of the preferred embodiments, with reference made to the accompanying drawings, wherein:

FIG. 1 is a schematic cross-sectional view of a prior-art FCQFN semiconductor package;

FIG. 2A is a schematic top view of another prior-art FCQFN semiconductor package;

FIG. 2B is schematic cross-sectional view taken along line 2B-2B of FIG. 2A;

FIG. 2C is a schematic view showing a delamination between a ground plane and an encapsulate of FIG. 2B;

FIG. 3A is a schematic top view of a leadframe-based flip chip semiconductor package and a lead frame thereof according to a first embodiment of the present invention;

FIG. 3B is a schematic cross-sectional view taken along line 3B-3B of FIG. 3A;

FIG. 4A is a schematic top view of a leadframe-based flip chip semiconductor package and a lead frame thereof according to a second embodiment of the present invention; and

FIG. 4B is a schematic cross-sectional view taken along line 4B-4B of FIG. 4A.

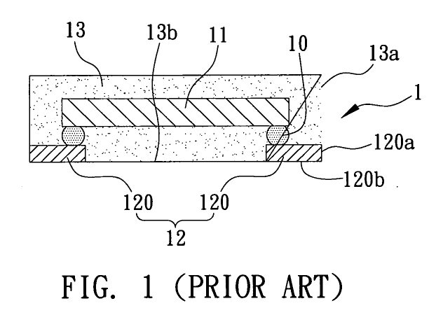

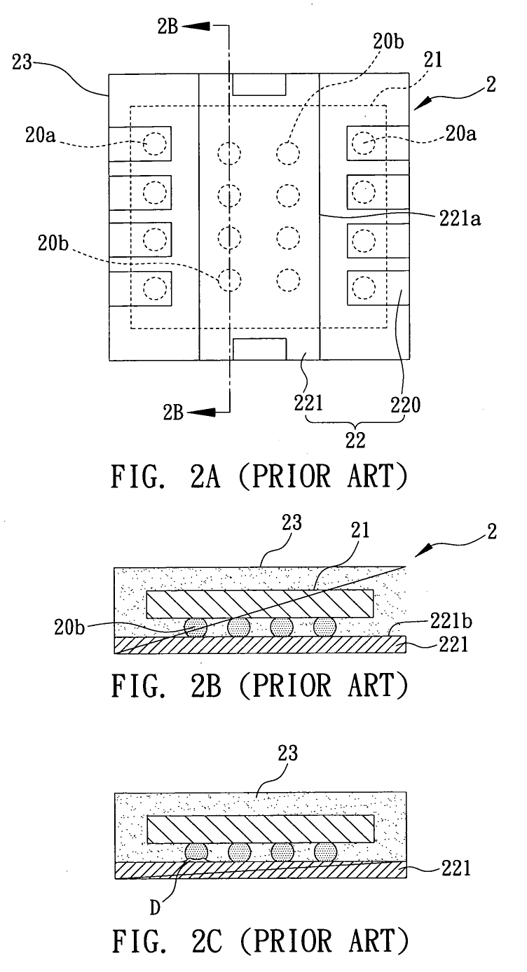

### DETAILED DESCRIPTION OF PREFERRED EMBODIMENTS

The following embodiments are described in sufficient detail to enable those skilled in the art to make and use the invention. It is to be understood that other embodiments would be evident based on the present disclosure, and that proves or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known configurations and process steps are not disclosed in detail.

Likewise, the drawings showing embodiments of the structure are semi-diagrammatic and not to scale and, particularly, some of the dimensions are for the clarity of presentation and are shown greatly exaggerated in the drawings. Similarly, although the views in the drawings for ease of description generally show similar orientations, this depiction in the drawings is arbitrary for the most part. Generally, the invention can be operated in any orientation.

For expository purposes, the term “horizontal” as used herein is defined as a plane parallel to the plane or surface of the substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “upper”, “over”, and “under”, are defined with respect to the horizontal plane.

### First Embodiment

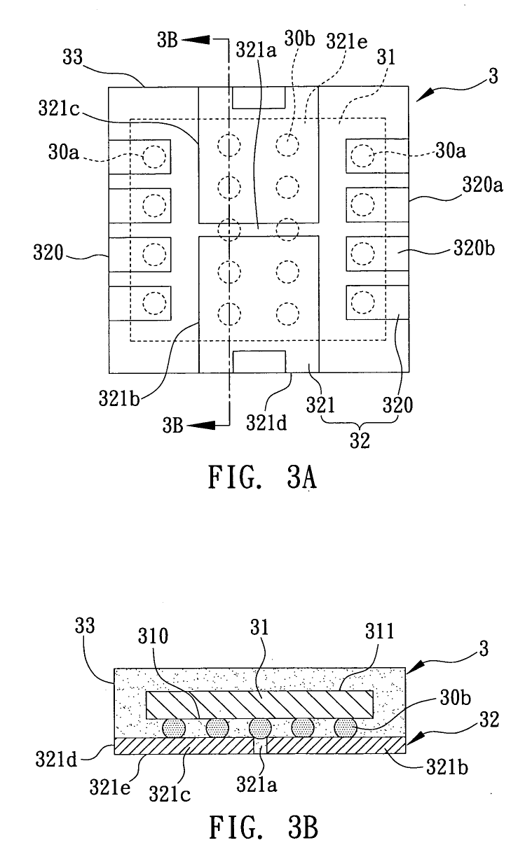

FIG. 3A is a schematic top view of a leadframe-based flip chip semiconductor package and a lead frame thereof according to a first embodiment of the present invention, and FIG. 3B is a schematic cross-sectional view taken along line 3B-3B of FIG. 3A.

Referring to FIGS. 3A and 3B, the leadframe-based flip chip semiconductor package 3 comprises: a chip 31 having an active surface 310 and an non-active surface 311; a lead frame 32 for carrying the chip 31; a plurality of solder bumps 30a and ground bumps 30b for electrically connecting the chip 31 to the lead frame 32; and an encapsulant 33 for encapsulating the chip 31, a portion of the lead frame 32, the solder bumps 30a, and the ground bumps 30b.

The chip 31 is mounted on the lead frame 32 by flip chip technique, such that the active surface 310 of the chip 31 is facing toward the lead frame 32, and the non-active surface 311 of the chip 31 is facing away from the lead frame 32.

Furthermore, the lead frame 32 may comprises a plurality of leads 320 and a ground plane 321 formed between the leads 320, wherein a slit 321a is formed in the middle of the ground plane 321 in a horizontal direction, so as to separate the ground plane 321 into two equal and symmetrical splitting portions 321b and 321c. The slit 321a may be linear and the width thereof is not limited. However, it preferably to form the slit 321a wide enough to allow encapsulating materials to be filled thereto, so as to form the encapsulant 33 free of voids. This thereby prevents popcorn effect during thermal cycling and enhances reliability of product.

It should be noted that the slit 321a may be formed by any physical or chemical techniques, and should not be limited to what has been described herein. For instance, the slit 321a may be formed by prior-art techniques such as stamping, cutting or sawing.

Moreover, before mounting the chip 31 on the lead frame 32, the solder bumps 30a and the ground bumps 30b may be respectively soldered on predetermined regions of the active surface 310 of the chip 31, wherein the predetermined regions may be located in position corresponding to the leads 320 or to portions of the ground plane 321. Therefore, after the chip 31 is mounted on the lead frame 32 via the solder bumps 30a and the ground bumps 30b by the flip-chip technique, the solder bumps 30a are soldered in position corresponding to the leads 320 and the ground bumps 30b are soldered in position corresponding to the ground plane 321. This thereby allows the present invention to transmit electrical signals and power signals between the chip 31 and the leads 320 via the solder bumps 30a, and even more, to transmit grounding signals and heat generated by the chip 31 to the ground plane 321 via the ground bumps 30b, such that the ground plane 321 can deliver the grounding signals and dissipate the heat to external environment.

In order to allow the ground plane 321 to provide electricity and heat dissipation effect all over the semiconductor package, portions of several ground bumps 30b are mounted across the slit 321a and electrically connected to the splitting portions 321b and 321c, thereby avoiding electrical connections and heat dissipation effect from being halted or affected by the formation of slit 321a.

Moreover, as the encapsulating materials are evenly filled into the slit 321a in a balance way, adhesion between the ground plane 321 and the encapsulant 33 can be greatly strengthened, after the encapsulant 33 is formed. In addition, formation of the slit 321a on the ground plane 321 can drastically reduce the thermal stress generated by the ground plane 321 during thermal cycling, thereby efficaciously avoiding delamination between the ground plane 321 and the encapsulant 33, and further ensuring reliability of the semiconductor package of the present invention.

Furthermore, after the encapsulant 33 is formed, an external lateral surface 320a and a bottom surface 320b of each of the leads 320 as well as an external lateral surface 321d and a bottom surface 321e of the ground plane 321 are uncovered from the encapsulant 33 as same as that of the prior art, and therefore further detailed description of such is omitted and not discussed hereinafter. Although it is not shown in the drawings, it is believed that one with ordinary skill in the art can understand that the non-active surface 311 of the chip 31 may be uncovered from the encapsulant 33 to enhance the efficiency of heat dissipation.

### Second Embodiment

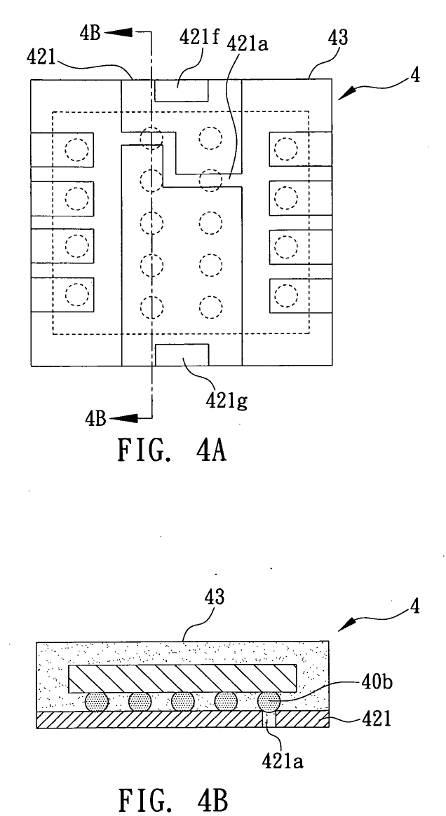

FIG. 4A is a schematic top view of a leadframe-based flip chip semiconductor package and a lead frame thereof according to a second embodiment of the present invention, and FIG. 4B is a schematic cross-sectional view taken along line 4B-4B of FIG. 4A.

As shown in the FIGS. 4A and 4B, the semiconductor package 4 fabricated according to a second embodiment of the present invention is similar to the foregoing semiconductor package 3, however one of the major differences therebetween is that the slit 421a formed on the ground plane 421 of the lead frame of the second embodiment comprises at least a bend or a turn. In other words, the slit 421a may be non-linear and tortuous, so as to provide more spaces for filling the encapsulant 43 thereto, thereby enhancing the adhesion between the ground plane 421 and the encapsulant 43. Moreover, it should be noted that the slit 421a may be formed in the middle of or anywhere of the ground plane 421, and should not be limited by what has been described herein.

Last but not the least, in order to reinforce the adhesion between the ground plane 421 and the encapsulant 43, recesses 421f and 421g may be formed on any ends of the ground plane 421, or specifically, formed on the distal ends of the ground plane 421 denting toward the middle thereof. Furthermore, there is no restriction on the shape and depth of the recesses 421f and 421g as long as the soldering process of the ground bumps 40b is not severely affected or impeded.

While the invention has been described in conjunction with exemplary preferred embodiments, it is to be understood that many alternative, modifications, and variations will be apparent to those skilled in the art in light of the foregoing description. Accordingly, it is intended to embrace all such alternatives, modifications, and variations that fall within the scope of the included claims. The scope of the claims, therefore, should be accorded the broadest interpretation so as to encompass all such modifications and similar arrangements. All matters hithertofore set forth herein or shown in the accompanying drawings are to be interpreted in an illustrative and non-limiting sense.

What is claimed is:

1. A leadframe-based flip chip semiconductor package, comprising:
a chip;
a lead frame having a plurality of leads and a ground plane disposed between the leads, wherein a slit is formed in the ground plane;
a plurality of solder bumps for electrically connecting the chip to the leads;
a plurality of ground bumps for electrically connecting the chip to the ground plane; and
an encapsulant for encapsulating the chip, the solder bumps, the ground bumps, and at least a portion of the lead frame, wherein at least a portion of the encapsulant is filled into the slit of the ground plane.

2. The flip chip semiconductor package of claim 1, wherein the slit is formed in a middle of the ground plane.

3. The flip chip semiconductor package of claim 1, wherein the slit is formed in position away from a middle of the ground plane.

4. The flip chip semiconductor package of claim 1, wherein the slit is linear.

5. The flip chip semiconductor package of claim 1, wherein the slit is non-linear.

6. The flip chip semiconductor package of claim 1, wherein portions of the ground bumps are mounted across the slit, so as to electrically connect two splitting portions of the ground plane that are separated by the slit.

7. The flip chip semiconductor package of claim 1, further comprising at least a recess formed on a distal end of the ground plane.

8. A lead frame, which is applicable to a flip chip semiconductor package partially encapsulated by an encapsulant, the lead frame comprising:
a plurality of leads; and
a ground plane formed between the leads, wherein the ground plane further comprises a slit for receiving at least a portion of the encapsulant.

9. The lead frame of claim 8, wherein the slit is formed in the middle of the ground plane.

10. The lead frame of claim 8, wherein the slit is formed in position away from the middle of the ground plane.

11. The lead frame of claim 8, wherein the slit is linear.

12. The lead frame of claim 8, wherein the slit is non-linear.

13. The lead frame of claim 8, further comprising at least a recess formed on a distal end of the ground plane.
